(19) United States
(12) Patent Application Publication
(10) Pub. No.: US 2026/0215042 A1
(43) Pub. Date: Jul. 23, 2026

(54) VISIBLE AND NEAR INFRARED AUTOMOTIVE LEDS

(71) Applicant: LUMILEDS LLC, San Jose, CA (US)

(72) Inventors: Peter Josef SCHMIDT, Aachen (DE); Thomas DIEDERICH, Stolberg (DE); Oleg Borisovich SHCHEKIN, San Francisco, CA (US); James David TARNE, Morgan Hill, CA (US)

(73) Assignee: LUMILEDS LLC, San Jose, CA (US)

(21) Appl. No.: 19/140,551

(22) PCT Filed: Jan. 23, 2024
(86) PCT No.: PCT/US2024/012535

§ 371 Date: Jun. 18, 2025

Related U.S. Application Data
(60) Provisional application No. 63/440,618, filed on Jan. 23, 2023.

(51) Int. Cl. H10H 20/851; H10H 20/01

(52) U.S. Cl. CPC H10H 20/8513; H10H 20/0361

(57) ABSTRACT

A lighting device and method of manufacturing a lighting device that improves the efficiency of converting light output by a light emitting diode (LED) to near-infrared light (NIR). To improve the efficiency, light emitted by the LED passes through a first phosphor layer that emits NIR light, and then the light passes through a second phosphor layer that absorbs light not absorbed by the first layer to generate additional light. In some instances, the additional light is in the visible spectrum.

This application claims the benefit of U.S. Provisional Application No. 63/440,618 filed Jan. 23, 2023, which is incorporated by reference as if fully set forth.

### BACKGROUND

Near infrared (NIR) emitting Light Emitting Diodes (LEDs) utilize Cr(III) absorption of blue primary LED light and either broadband NIR emission of the Cr(III) center or energy transfer from Cr(III) to another emitter like Yb(III). Since the absorption cross section of Cr(III) in the blue spectral range is limited, a significant amount of blue primary emission light is present in the LED emission spectrum leading to a blue color impression and/or a loss of light output from the lighting system.

### SUMMARY

A lighting device and method of manufacturing a lighting device that improves the efficiency of converting light output by alight emitting diode (LED) to near-infrared light (NIR). To improve the efficiency, light emitted by the LED passes through a first phosphor layer that emits NIR light, and then the light passes through a second phosphor layer that absorbs light not absorbed by the first layer to generate additional light. In some instances, the additional light is in the visible spectrum.

### BRIEF DESCRIPTION OF THE DRAWINGS

A more detailed understanding can be had from the following description, given by way of example in conjunction with the accompanying drawings wherein:

FIG. 1 is a schematic representation of an example lighting device;

FIG. 2 is a schematic representation of another example lighting device;

FIG. 3 is a schematic representation of another example lighting device;

FIG. 4 is a schematic representation of another example lighting device;

FIG. 5A is a graph showing spectrum of example reflectance spectra of NIR phosphors.

FIG. 5B is a graph showing an example emission spectrum of primary phosphor ceramic under blue light (443 nm) excitation.

FIG. 5C is a graph showing an example emission spectrum of a white light+NIR light emitting LED source;

FIG. 5D is a graph showing spectra of example LED light sources with power phosphors;

FIG. 6 is a flow diagram of an example method of manufacturing lighting devices;

FIG. 7 is a diagram of an example vehicle headlamp system; and

FIG. 8 is a diagram of another example vehicle headlamp system.

### DETAILED DESCRIPTION

Examples of different light illumination systems and/or light emitting diode (‘LED’) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only, and they are not intended to limit the disclosure in any way. Like numbers refer to like elements throughout.

It will be understood that, although the terms first, second, third, etc., may be used herein to describe various elements, these elements should not be limited by these terms. These terms may be used to distinguish one element from another. For example, a first element may be termed a second element, and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element, or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,” “lower,” “horizontal,” or “vertical” may be used herein to describe a relationship of one element, layer, or region to another element, layer, or region as illustrated in the figures. It will be understood that these terms are intended to encompass different orientations of the device in addition to the orientation depicted in the figures.

Active infrared (IR) night vision for automotive driving assistance typically combines near-infrared (NIR) light in the wavelength range up to 1000 nm with silicon detector-based camera systems such as charge-coupled device (CCD) cameras that are especially sensitive in the NIR wavelength range with peak quantum efficiencies in the 750 to 900 nm wavelength range. Common standalone NIR illuminators applied for active illumination typically consist of arrays of monochrome InGaAs LEDs with 850 nm or 940 nm emission.

Phosphor-converted NIR emitting LEDs may be based on Cr(III) absorption of blue primary LED light and either broadband NIR emission of the Cr(III) center or energy transfer from Cr(III) to another emitter like Yb(III). Since the absorption cross-section of Cr(III) in the blue spectral range is limited, a significant amount of blue primary emission light may be present in the LED emission spectrum leading to a blue color impression. In order to comply with automotive lighting regulations, embodiments described herein may down-convert part of the remaining blue primary light emission into the visible spectrum. For example, some embodiments utilize the yellow spectral range to realize a white light appearance for the human eye with a correlated color temperature that matches that of regular white-emitting phosphor-converted LEDs.

As described in U.S. Pat. No. 10,971,658 entitled “Infrared emitting device,” Cr(III) absorbs not only blue light but also red light. U.S. Pat. No. 10,971,658 is hereby incorporated by reference herein in its entirety. As a result, the selection of both visible-emitting phosphors and NIR-emitting phosphors is critical to realize the wanted spectral properties.

A known disadvantage of direct emitting InGaAs IR illuminator arrays used for active night vision systems is the temperature sensitivity of both the total radiation output power and its spectral distribution, which makes illumination systems and optics bulky and expensive. This hinders integration into automotive front lighting systems. Moreover, monochromatic IR radiation only allows to sense grey scale contrast of the scene in front of the camera system and thus makes classification difficult. The embodiments described herein may resolve these issues by providing phosphor-converted NIR LED light sources that can be easily integrated into automotive front lighting systems by emitting a combination of visible and broadband NIR light. The visible spectral range may be perceived as white light, and the broadband NIR light emitted may have an emission maximum in the 700-1050 nm wavelength range. The broadband IR light may also emit at longer wavelength ranges such as 1100-1700 nm. Such light may be advantageous for Short-wave Infrared (SWIR) camera systems.

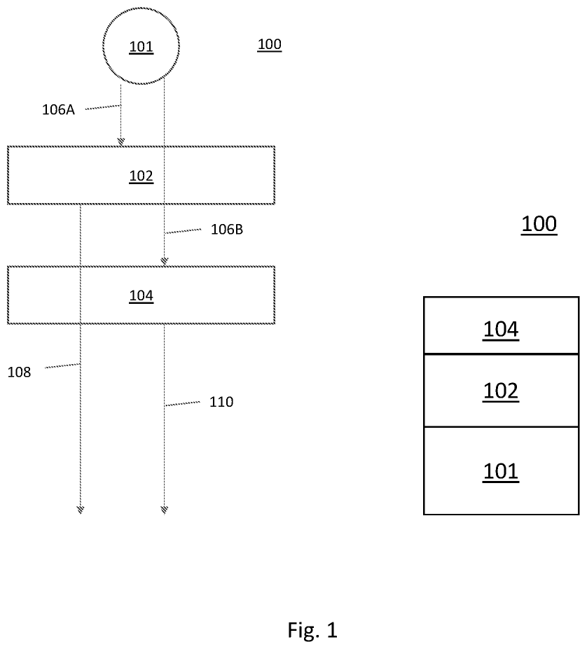

FIG. 1 are two block diagrams of an example lighting device 100. In the example illustrated in FIG. 1, a light source 101, which may be an LED or any other suitable source, emits light comprising first light (also commonly referred to as pump light) 106A and first light 106B. In FIG. 1, 106A and 106B may be taken to be two photons of pump light emitted by the light source 101. One of ordinary skill in the art will understand that an LED, for example, may emit a spectrum of light in all directions. The first light 106A and first light 106B, however, enable one to easily envision how different photons of light may be treated as they pass through the lighting device 100. In some instances, the first light 106B may have the same wavelength as the first light 106A. In other instances, the wavelengths are different.

Two wavelength converting layers may be provided or stacked above the LED 101, as easily seen on the right side of FIG. 1. A first wavelength converting layer 102 may be an NIR phosphor layer and may be located adjacent a top surface of the LED 101. A second wavelength converting layer 104 may be a second wavelength converting layer 104 and may be adjacent a top surface of the first wavelength converting layer 102 or, in other words, the first wavelength converting layer 102 may be between the light source 101 and the second wavelength converting layer 104.

In the example illustrated in FIG. 1, the first light 106A may have a wavelength in the 430-470 nm wavelength range. The first light 106A may be absorbed by the first wavelength converting layer 102. In response to absorbing the first light 106A, the first wavelength converting layer 102 may emit a second light 108. The second light 108 may have a wavelength in the 700-1050 nm wavelength range.

Normally, some amount of the pump light from the light source 101 will not be absorbed by the first wavelength converting layer 102 and, thus, will pass through the first wavelength converting layer 102 unconverted. First light 106B represents such light. In the example illustrated in FIG. 1, the first wavelength converting layer 102 fails to absorb the first light 106B, and the first light 106B passes through the NIR phosphor unconverted.

But for the presence of the second wavelength converting layer 104, the first light 106B, and any other rays that may pass through the first wavelength converting layer 102 unconverted, would be emitted from the lighting device 100 as typically a blue appearing pump light. In applications where the color appearance of the light to the human eye is important, such as in automotive headlights, which are meant to appear white, and brake lights, which are meant to appear red, a blue emission color from the lighting device is extremely undesirable. As can be seen in FIG. 1, however, the blue appearing pump light 106B may be absorbed by the second wavelength converting layer 104, which may emit a third light 110, which may have a peak wavelength in the 540-560 nm wavelength range when the lighting device is configured for use in a headlight system. In addition, the third light 110 may have a peak wavelength in the range 615-640 nm when the lighting device 100 is configured for use in a taillight system. The second light 108 is not absorbed by the second wavelength converting layer 104 and passes through the second wavelength converting layer 104. The second light 108 and the third light 110 constitute the output light of the lighting device 100. Accordingly, the lighting device 100 may provide for an LED for automotive lighting that may advantageously emit both NIR and visible light, the visible light being in a spectrum that is usable for the particular lighting application, such as yellow for headlights and red for taillights. In particular for headlights, the yellow light may be combined with a blue light to generate a white light. The visible light may also be turquoise (cyan) to apply such light sources for the vision systems of autonomous vehicles (AVs).

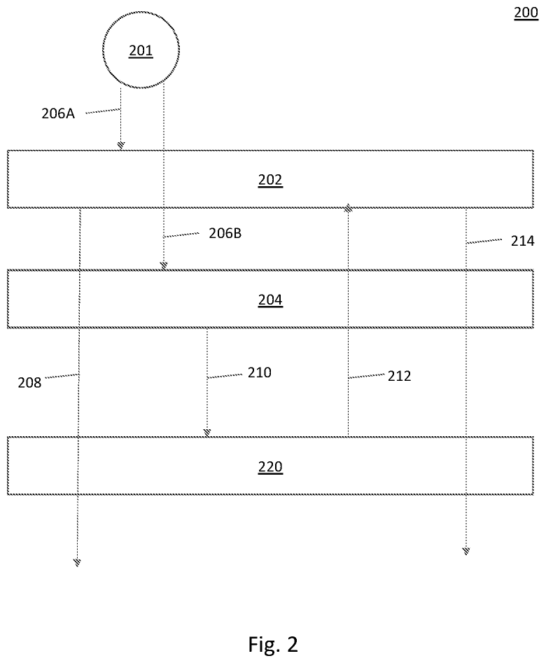

FIG. 2 is a block diagram of another example lighting device 200. In this embodiment, the output of the lighting device 200 is defined by the NIR phosphor layer 202. In the example illustrated in FIG. 2, a light source 201, which may be an LED or any other suitable source, emits light comprising first light (also commonly referred to as pump light) 206A and first light 206B. In FIG. 2, 206A and 206B may be taken to be two photons of pump light emitted by the light source 201. One of ordinary skill in the art will understand that an LED, for example, may emit a spectrum of light in all directions. The first light 206A and first light 206B, however, enable one to easily envision how different photons of light may be treated as they pass through the lighting device 200. In some instances, the first light 206B may have the same wavelength as the first light 206A. In other instances, the wavelengths are different

Similar to lighting device 100, the converting layers (202, 204) and the reflective layer 220 of the lighting device 200 may be stacked. A first wavelength converting layer 202 may be an NIR phosphor layer and may be located adjacent a top surface of the LED 201. A second wavelength converting layer 204 may be a visible phosphor layer 204 and may be adjacent a top surface of the first wavelength converting layer 202 or, in other words, the first wavelength converting layer 202 may be between the light source 201 and the second wavelength converting layer 204.

Like in FIG. 1, in the example illustrated in FIG. 2, the first light 206A may have a wavelength in the 430-470 nm wavelength range. The first light 206A may be absorbed by the NIR phosphor layer 202. In response to absorbing the first light 206A, the NIR phosphor layer 202 may emit a second light 208. The second light 208 may have a wavelength in the 700-1050 nm wavelength range.

Like in FIG. 1, First light 206B represents light from the light source 201 that is not be absorbed by the NIR phosphor layer 202 and passes through the NIR phosphor layer 202 unconverted. However, in lighting device 200 a reflective layer 220 is added. In some instances, the reflective layer 220 is a dichroic filter element. A dichroic filter element is particularly useful for a light source 201 with a saturated color impression. In this case, the dichroic filter improves the efficiency of the lighting device 200 by converting a higher percentage of the light output from the light source 201 to the output of the lighting device 200.

In response to the second phosphor layer 204 absorbing the first light 206B, the second phosphor layer 204 emits a third light 210. The third light 210 may have a peak wavelength within the 615 nm to 635 nm range.

The third light 210 is then reflected by reflective layer 220 to form a fourth light 212. The fourth light 212 pass through the second phosphor layer 204 and is absorbed by the NIR phosphor layer 202. In response to absorbing the fourth light 212, the NIR phosphor layer 202 emits the fifth light 214. The fifth light 214 may have a wavelength in the 700-1050 nm range.

The fifth light 214 is not absorbed by the second phosphor layer 204, and passes through the second phosphor layer 204 and the reflective layer 220. The second light 208 is not absorbed by the second phosphor layer 204, and passes through the second phosphor layer 204 and the reflective layer 220. The second light 208 and the fifth light 214 constitute the output light of the lighting device 200.

Accordingly, the lighting device 200 may provide NIR light for autonomous driving applications with higher efficiency than is found in conventional system.

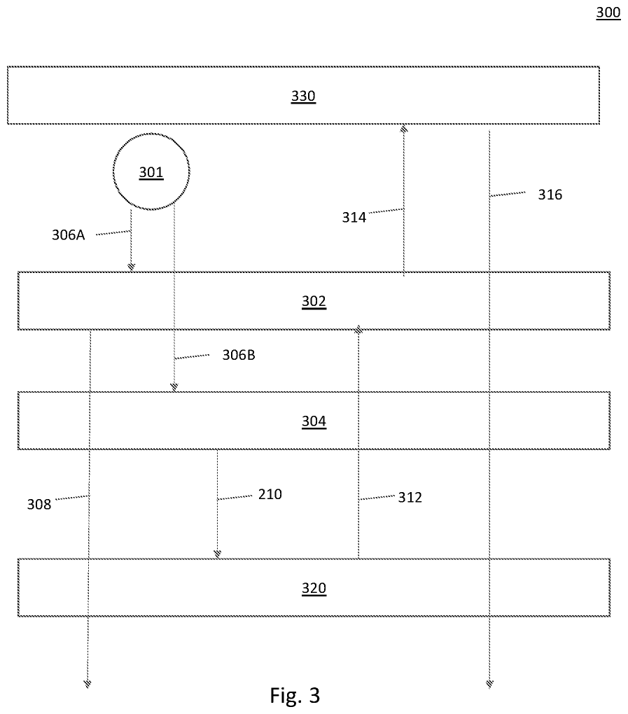

FIG. 3 is a block diagram of another example lighting device 300. The lighting device 300 is similar to lighting device 200, however lighting device 300 adds an additional reflective layer 330. Similar to lighting device 200, lighting device 300 includes a light source 301, which may be an LED or any other suitable source, emits light comprising first light 306A and first light 306B. The first light 306A may have a peak wavelength in the 430-470 nm wavelength range. The first light 306A is then absorbed by the NIR phosphor layer 302. In response to absorbing the first light 306A, the NIR phosphor layer 302 emits a second light 308. The second light 308 may have a peak wavelength in the 700-1050 nm wavelength range.

The NIR phosphor layer 302 fails to absorb the first light 306B, and the first light 306B passes through the NIR phosphor and is absorbed by a second phosphor layer 304. In some instances, the first light 306B may have the same wavelength as the first light 306A. In other instances, the wavelengths are different.

In response to the second phosphor layer 304 absorbing the first light 306B, the second phosphor layer 304 emits a third light 310. The third light 310 may have a peak wavelength of 615-635 nm.

The third light 310 is then reflected by the first reflective layer 320 to form a fourth light 312. The fourth light 312 pass through the second phosphor layer 304 and is absorbed by the NIR phosphor layer 302. In response to absorbing the fourth light 312, the NIR phosphor layer 302 emits the fifth light 314. The fifth light 314 may have a peak wavelength of wavelength in 700-1050 nm wavelength range.

The fifth light 314 is then reflected by the second reflective layer 330 to generate a sixth light 316. The sixth light passes through the NIR phosphor layer 302, the second phosphor layer 204, and the first reflective layer 320 without being absorbed or reflected.

The second light 308 is not absorbed by the second phosphor layer 304, and passes through the second phosphor layer 304 and the first reflective layer 320. The second light 308 and the sixth light 316 constitute the output light of the lighting device 300.

Accordingly, the lighting device 200 may provide NIR light for autonomous driving applications with higher efficiency than is found in conventional system.

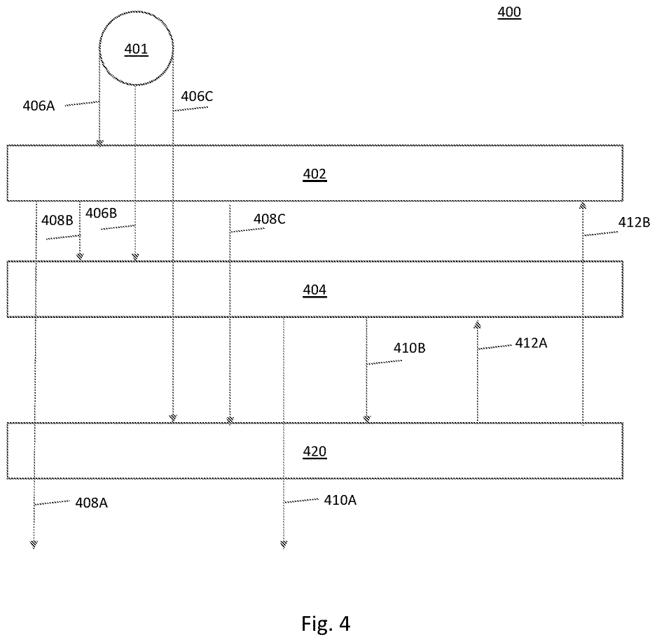

FIG. 4 is a block diagram of another example lighting device 400. The lighting device 400 is similar to the lighting device 200. However, in lighting device 400, the second phosphor layer 404 may also absorb the 412a light, and the reflective layer 420 may also have filter characteristics such that only blue light is back-reflected and the non-blue light is allowed to pass through the reflective layer 420. This “light recycling” allows the 404 layer to be thinner and the device 400 to be more efficient when the light source 401 has a saturated color impression.

For example, in lighting device 400, a first portion of the first light 406A is absorbed by the first phosphor layer 402, a second portion of the first light 406B is absorbed by the second phosphor layer 404, and a third portion of the first light 406C is reflected by the reflective layer 420.

In response to absorbing the first portion of the first light 406A, the first phosphor layer 402 may emit a second light that includes a first portion 408A, a second portion 408B and a third portion 408C. The first portion of the second light 408a may have a wavelength in the 700-1050 nm wavelength range.

The second portion of the first light 406B passes through the first phosphor layer 402 and is absorbed by the second phosphor layer 404. In response to absorbing the second portion of the first light 406B and the second portion of the second light 408B, the second phosphor layer 404 emits a third light (410A, 410B). The first portion of the third light 410A passes through the reflective layer 420.

The reflective layer 420 generates a fourth light (412A, 412B) as a result of reflecting the third portion of the first light 406C, the third portion of the second light 408C, and the second portion of the third light 410B. For example, the reflective layer 420 reflects the portion of the first, second and third lights that have a wavelength in the range of 400-590 nm.

The first portion of the fourth light 412A is absorbed by the second phosphor layer 404. In response to absorbing the first portion of the fourth light 412A, the second phosphor layer 404 emits the third light (410A, 410B).

The second portion of the fourth light 412B passes through the second phosphor layer 404 and is absorbed by the first phosphor layer 402. In response to absorbing the second portion of the fourth light 412B, the first phosphor layer 402 emits the second light (408A, 408B, 408C).

The first portion of the second light 408A and the first portion of the third light 410A constitute the output light of the lighting device 400.

In embodiments, the NIR phosphor layer (102/202/302/402) absorbs the light emitted by the light sources (101/201/301/401) and emits light in the NIR. In some instances, the NIR phosphor layer is provided in polycrystalline ceramic form. For example, the NIR phosphor layer may be a gadolinium lutetium scandium gallium garnet doped with chromium (GSLGG) as described in U.S. Pat. No. 10,770,627, which is hereby incorporated by reference in its entirety. For example, the NIR phosphor layer may include Cr(III) doped garnet phosphors such as:

$${Gd}_{3 - x} {RE}_{x} {Sc}_{2 - y - z} {Ln}_{y} {Ga}_{3 - w} {Al}_{w} {O}_{12} : {Cr}_{z} ( Ln = Lu , Y , Yb , Tm ; RE = La , Nd ) ,$$

$$where 0 \leq x \leq 3 ; 0 \leq y \leq 1.5 ; 0 \leq z \leq 0.3 ; and 0 \leq w \leq 2 such as$$

$${Gd}_{2.8} {La}_{0.2} {Sc}_{1.7} {Lu}_{0.2} {Ga}_{3} {O}_{12} : {Cr}_{0.1} or$$

$${Gd}_{2.66} {Yb}_{0.2} {Sc}_{1.75} {Lu}_{0.3} {Ga}_{2} {AlO}_{12} : {Cr}_{0.1}$$

In other embodiments, the NIR phosphor layer (102/202/302) layer is an lithium scandium magnesium silicate doped with chromium (LSMSO) as described in (U.S. patent application Ser. No. 16/829,932), which is hereby incorporated by reference in its entirety. For example, the NIR phosphor layer may include Cr(III) doped pyroxene phosphors such as:

$${E}_{1 - w} {Sc}_{1 - x - y - u - w} {M}_{y} {Z}_{u} {A}_{2 w} {Si}_{2 - z - u} {Ge}_{z} {Al}_{u} {O}_{6} : {Cr}_{x} , such as$$

$${Li}_{1 - w} {Sc}_{1 - x - w} {Mg}_{2 w} {Si}_{2} {O}_{6} : {Cr}_{x} ( 0.1 \leq w \leq 0.4 )$$

In some embodiments, the NIR phosphor layer (102/202/302) contains borates like ScBO3:Cr as disclosed in (U.S. patent application Ser. Nos. 16/827,857 and 18/074,589), which are hereby incorporated by reference in its entirety. For example, the NIR phosphor layer may include Cr(III) doped borate phosphors such as:

$${Sc}_{1 - x - y} {A}_{y} {BO}_{3} : {Cr}_{x} ( A = Lu , In , Yb , Tm , Y , Ga , Al ; 0 < x \leq 0.5 , 0 < y \leq 0.9 )$$

In alternative embodiments, the IR phosphor layer (102/202/302) contains spinels as disclosed in U.S. patent application Ser. No. 17/035,233 which is hereby incorporated by reference in its entirety. AE_{1-x-z}A_{z+0.5(x-y)}D_{2+0.5(x-y)-z-u}E_{z}O₄:Ni_{y}, Crᵤ where AE=Mg, Zn, Co, or Be, or mixtures thereof, A=Li, Na, Cu, or Ag, or mixtures thereof, D=Ga, Al, B, In, or Sc, or mixtures thereof, and E=Si, Ge, Sn, Ti, Zr, or Hf, or mixtures thereof; where 0≤x≤1, 0<y≤0.1, 0≤z≤1, 0≤u≤0.2, such as Li_{0.5-0.5x}(Ga,Sc)_{2.5-0.5x-y}O₄:Niₓ,Cr_{y} (where 0≤x≤1, 0<y≤0.1)

The second wavelength converting layer 104 emits a third light 110 in the visible spectral range. The second wavelength converting layer 104 may be provided in the form of a polycrystalline ceramic or in the form of a powder, with the powder particles being attached to the first wavelength converting layer 102 by means of a matrix material like silicone, amorphous alumina or a glass.

In some instances, the second wavelength converting layer 104 shows broadband yellow emission. For example, the visible phosphor layer may include Y_{3-x-y}RE_{y}Al_{5-z}Ga_{z}O₁₂:Ceₓ (RE=Gd, Lu, Yb), where 0<x≤0.1; 0≤y≤0.5; 0≤z≤0.3 as described in “Broadband spectral conversion of visible light to near-infrared emission via energy transfer from Ce³⁺ to Nd³⁺/Yb³⁺ in YAG” Journal of Materials Research, 26(5), 689-692. doi:10.1557/jmr.2010.84, which is hereby incorporated by reference in its entirety. Alternatively, the second wavelength converting layer 104 may include:

$${R}_{3 - x - y + w 2} {A}_{1.5 x + y - w 2} {Si}_{6 - w 1 - w 2} {Al}_{W 1 + w 2} {O}_{y + w 1} : {Ce}_{z} ( R = La , Gd , Lu , Y and Sc , A = Ba , Sr , Ca , Mg and Zn ) ,$$

$$where$$

$$( 1 / 7 ) ≦ ( 3 - x - y - z + w 2 ) / 6 < ( 1 / 2 ) , 0 < ( 1.5 x + y - w 2 ) / 6 < ( 9 / 2 ) ,$$

$$0 < x < 3 , 0 ≦ y ≦ 2 , 0 < z < 1 , 0 ≦ w 1 ≦ 5 , 0 ≦ w 2 ≦ 5 , and$$

$$0 ≦ w 1 + w 2 ≦ 5. ) such as {( {La}_{0.8} {Y}_{0.2} )}_{3 - z} {Si}_{6} {N}_{11} : {Ce}_{z}$$

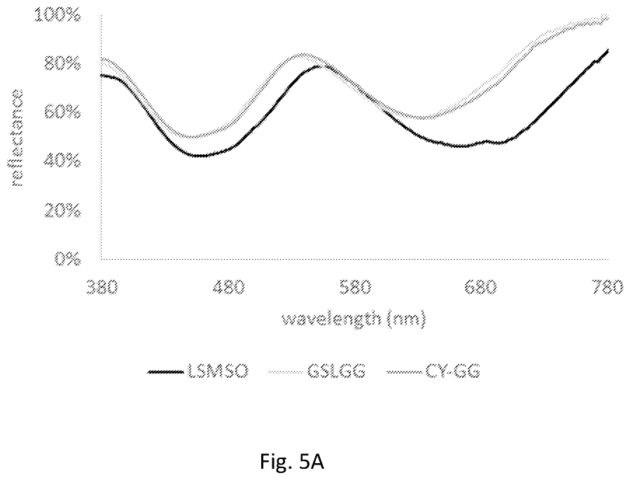

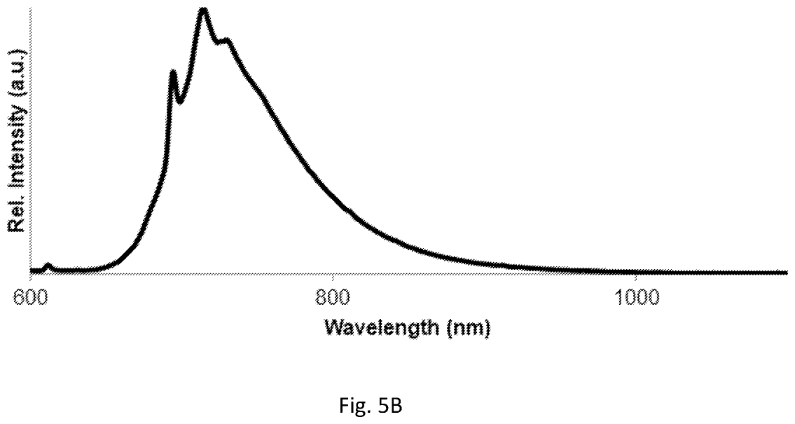

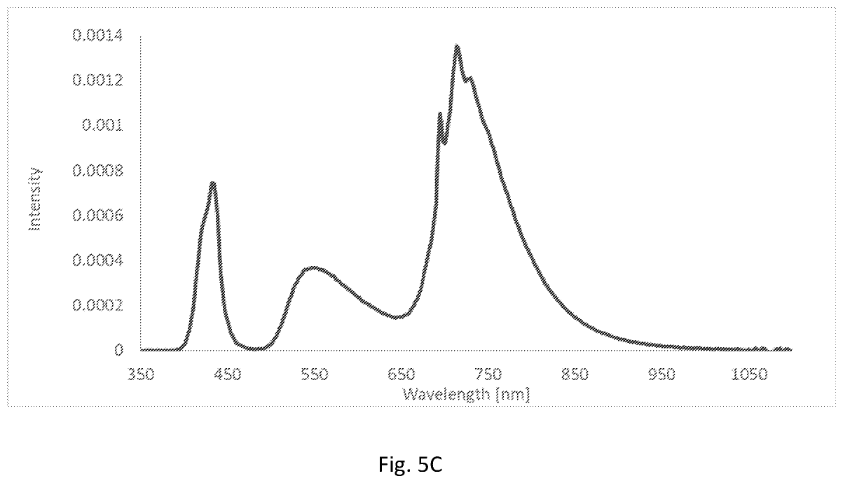

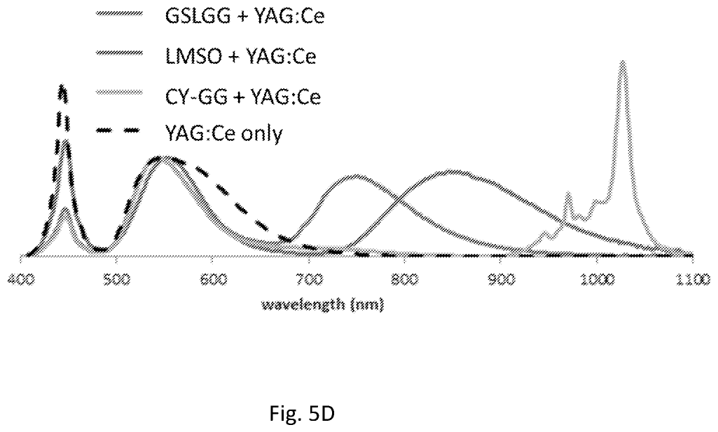

In other instances, the second wavelength converting layer 104 may contain an orange to red emitting phosphor to lower the correlated color temperature of the white spectrum. This is especially useful for mixed powder for systems containing first and second phosphors since the absorption of the first phosphor in the red spectral range (FIG. 5A) decreases the red emission content of the white spectrum. Suitable phosphor systems are:
M₂₋ₓSi_{5-y}Al_{y}O_{y}N_{8-y}:Euₓ (M=Ba, Sr, Ca), such as, for example Ba_{0.4}Sr_{1.58}Si_{4.98}Al_{00.2}O_{0.02}N_{7.98}:Eu_{00.2}
CASN or SCASN type phosphors of composition M₁₋ₓSiAlN₃:Euₓ (M=Sr, Ca) such as, for example Sr_{0.90}Ca_{0.086}SiAlN₃:Eu_{0.0004}
SLA or SLAO type phosphors Sr₁₋ₓLi_{1+y}Al_{3-y+z}Si_{z}O_{2y-z}N_{4-2y+z}:Euₓ, such as, for example Sr_{0.993}LiAl₃N₄:Eu_{0.007} or Sr_{0.994}Li₂Al_{1.995}Si_{0.005}O_{1.995}N_{2.005}:Eu_{0.006}

Broadband yellow emission of the second wavelength converting layer 104 may be desirable when the lighting device 100 is incorporated in a headlight of a vehicle. On the other hand, orange to red emission of the second wavelength converting layer 104 may be desirable when the lighting device 100 is incorporated in the tail light of the vehicle.

In some instances, the second phosphor layer 204/304 is provided as a polycrystalline ceramic layer. The second phosphor layer 204/304 may also be provided as a film of phosphor particles in a silicone matrix with and without an additional carrier material such a glass

In some instances, the first reflective layer 220/320 and the second reflective layer 330 are provided as dichroic coating layers comprising sequential stacks of low refractive index and high reflective index oxide materials such as silica and niobia [inventors to describe

FIG. 4 shows the Spectra of pcLEDs comprising YAG:Ce powder phosphor only (dashed curve) and mixtures of YAG:Ce powder phosphor with NIR emitting phosphor powders showing absorption of red light emitted by YAG:Ce second phosphor by the NIR emitting first phosphors. Specifically, FIG. 4 shows an orientating experiment where powders of first and second phosphors have been mixed with silicone and dispensed into midpower packages with blue light emitting InGaN dies.

FIG. 5A illustrates a spectra of example reflectance spectra of NIR phosphors showing absorption of the phosphors in both blue and red spectral ranges.

FIG. 5B illustrates an example emission spectrum of primary phosphor ceramic under blue light (443 nm) excitation showing emission in the 700 nm wavelength range.

FIG. 5C illustrates a graph showing an example emission spectrum of a white+NIR emitting light source comprising a ceramic+phosphor layer on top of a high-power blue LED source according to some embodiments.

In the example shown in FIG. 5D, a second phosphor, a commercial Y₃Al₅O₁₂:Ce phosphor powder (NYAG4454 available from Internatix), is applied, and a first phosphor, “GSLGG” of composition Gd_{2.85}Sc_{1.75}Lu_{0.3}Ga₃O₁₂:Cr_{0.1}, “LSMSO” of composition Li_{0.75}Sc_{0.7}Mg_{0.5}Si₂O₆:Cr_{0.05}, or “CY-GG” of composition Gd_{2.66}Sc_{1.75}Lu_{0.3}Ga₂AlO₁₂:Cr_{0.1}, Yb_{0.2} has been selected. The respective powder mixtures have been dispersed in a silicone resin and dispensed into LED packages comprising blue emitting InGaN primary light emitting LEDs. FIG. 5D shows the obtained emission spectra of the LEDs comprising the two phosphor combinations (solid curves) that are characterized by significant reabsorption of the emitted red light of the YAG:Ce second phosphor by the various NIR emitting first phosphors if compared with the spectrum of the YAG:Ce only containing LED (dashed curve in FIG. 5D, powder reflectance spectra of NIR phosphors FIG. 5A). This reabsorption leads to high correlated color temperatures (>6500 K) of the balanced white spectrum and is not desired for e.g., application in car front lighting (preferably, the white color point matches the white color point of LEDs only containing the second phosphor to enable, e.g. integration of white only emitting LEDs and white+NIR emitting LEDs into segmented front lighting engines). Some embodiments of the present invention attempt to minimize the reabsorption of the emitted second phosphor light by the first phosphor.

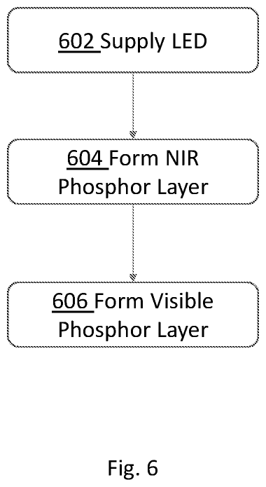

FIG. 6 is a flow diagram of the example method of manufacturing lighting devices such as lighting device 100. In step 602, the light source 101 is provided. In step 604, in some instances, the NIR phosphor layer is formed by mixing 3 parts of the GSLGG phosphor of composition Gd_{2.85}Sc_{1.75}Lu_{0.3}Ga₃O₁₂:Cr_{0.1} with 1 part of a heat curable silicone encapsulant and dispensed onto a LED package comprising a blue emitting LED die. In step 606, after sedimentation and curing of the silicone matrix, the visible phosphor layer is formed by mixing 1 part of YAG:Ce phosphor (NYAG4454 available from Internatix Corp.) with 4 parts of a heat curable silicone encapsulant and dispensed onto the layer comprising the first phosphor to realize a white light spectrum (CIE x,y=0.328, 0.354) with a correlated color temperature of 5700K and a CRI (Ra8) of 64 (FIG. 4). The power ratio of NIR light (700-1050 nm) to visible light (400-700 nm) is 1.58 and the electrical to NIR power conversion efficiency W_{NIR}/W_{Elec}=19%.

In order to provide the NIR phosphor applied in step 604, the GSLGG phosphor is synthesized by the following procedure. 61.4 g gadolinium oxide (Treibacher, >3N8), 14.89 g scandium oxide (Treibacher, 4N), 7.28 g lutetium oxide (NEO, 4N), 34.64 g gallium oxide (Dowa, 4N), 0.925 g chromium (III) oxide (Materion, 2N5) and 1.956 g gadolinium fluoride (Materion, 4N) have been mixed by ball milling and fired twice at 1550° C. with intermediate milling. After crushing the phosphor powder cake and milling to the desired particle size (mean particle diameter 15-16 μm) the phosphor is washed with water. After sedimentation, the phosphor is dried and screened through a 50 μm sieve. The phosphor crystallizes in the cubic garnet structure with a lattice constant of 12.487 Ångström and a density of 6.73 g/cm³.

In other instances, the NIR phosphor needed for step 604 and provided in form of a polycrystalline ceramic layer is synthesized by the following procedure. 87.6 g gadolinium oxide (Treibacher, 3N5), 9.84 g gadolinium oxide (Liyang Solvay, 4N), 45.25 g gallium oxide (Dowa, 4N), 1.356 g chromium (III) oxide, 20.99 g aluminum oxide (Baikowski, 4N), and 0.043 g silica (fumed, Evonik) are mixed by ball milling in ethanol with a dispersant (Malialim). After the addition of a polyvinylbutyral binder vehicle, ceramic tapes are cast, stacked, laminated, and cut into ceramic green bodies with a thickness of 200 μm. After binder burnout, ceramic green bodies are sintered at 1550° C. to obtain sintered ceramics that can be attached to primary LED light sources after dicing into platelets. The cubic garnet main phase shows a lattice constant of 12.237 Ångstrôm. FIG. 5B shows an example of the emission spectrum of the GGAG ceramic with a centroid wavelength of 750.0 nm and a FWHM of 79.9 nm.

Then in step 606 the visible phosphor layer is formed. In some instances, the visible phosphor layer is formed by mixing 1 part of YAG:Ce phosphor (NYAG4752 available from Internatix Corp.) with 4 parts of a heat curable silicone encapsulant and dispensed onto the surface of the GGAG ceramic layer. After curing of the silicone matrix, a white+NIR emitting LED light source is being obtained by attaching the converter structure to a 445 nm emitting InGaN primary LED light source. The final device shows a correlated color temperature of 5517 K, color coordinates CIE x,y=0.332, 0.328, and color rendering indices Rₐ8=60 and R₉=17 with a spectral power distribution as shown in FIG. 5C.

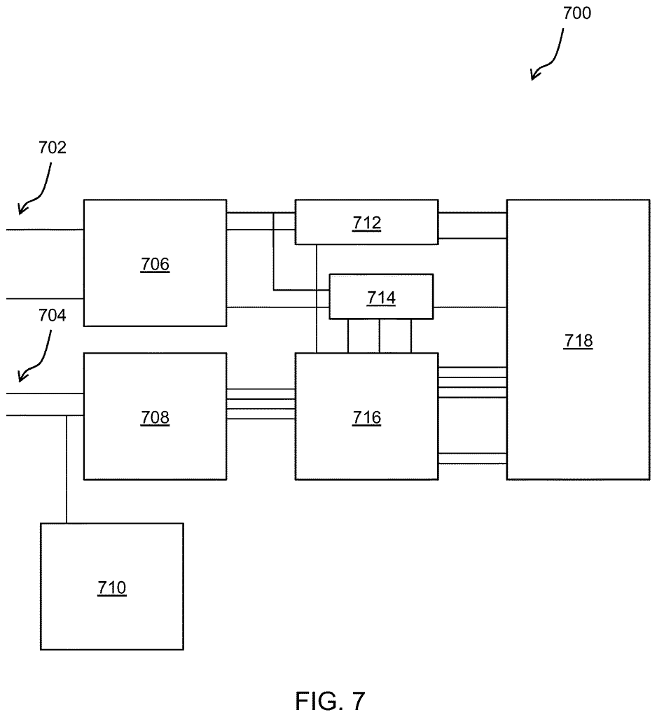

FIG. 7 is a diagram of an example vehicle headlamp system 700 that may incorporate one or more of the embodiments and examples described herein. The example vehicle headlamp system 700 is illustrated in FIG. 7 includes power lines 702, a data bus 704, an input filter and protection module 706, a bus transceiver 708, a sensor module 710, an LED direct current to direct current (DC/DC) module 712, a logic low-dropout (LDO) module 714, a micro-controller 716 and an active head lamp 718.

The power lines 702 may have inputs that receive power from a vehicle, and the data bus 704 may have inputs/outputs over which data may be exchanged between the vehicle and the vehicle headlamp system 700. For example, the vehicle headlamp system 700 may receive instructions from other locations in the vehicle, such as instructions to turn on turn signaling or turn on headlamps, and may send feedback to other locations in the vehicle if desired. The sensor module 710 may be communicatively coupled to the data bus 704 and may provide additional data to the vehicle headlamp system 700 or other locations in the vehicle related to, for example, environmental conditions (e.g., time of day, rain, fog, or ambient light levels), vehicle state (e.g., parked, in-motion, speed of motion, or direction of motion), and presence/position of other objects (e.g., vehicles or pedestrians). A headlamp controller that is separate from any vehicle controller communicatively coupled to the vehicle data bus may also be included in the vehicle headlamp system 700. In FIG. 7, the headlamp controller may be a micro-controller, such as micro-controller (pc) 716. The micro-controller 716 may be communicatively coupled to the data bus 704.

The input filter and protection module 706 may be electrically coupled to the power lines 702 and may, for example, support various filters to reduce conducted emissions and provide power immunity. Additionally, the input filter and protection module 706 may provide electrostatic discharge (ESD) protection, load-dump protection, alternator field decay protection, and/or reverse polarity protection.

The LED DC/DC module 712 may be coupled between the input filter and protection module 106 and the active headlamp 718 to receive filtered power and provide a drive current to power LEDs in the LED array in the active headlamp 718. The LED DC/DC module 712 may have an input voltage between 7 and 18 volts with a nominal voltage of approximately 13.2 volts and an output voltage that may be slightly higher (e.g., 0.3 volts) than a maximum voltage for the LED array (e.g., as determined by factor or local calibration and operating condition adjustments due to load, temperature or other factors).

The logic LDO module 714 may be coupled to the input filter and protection module 706 to receive the filtered power. The logic LDO module 714 may also be coupled to the micro-controller 716 and the active headlamp 718 to provide power to the micro-controller 716 and/or electronics in the active headlamp 718, such as CMOS logic.

The bus transceiver 708 may have, for example, a universal asynchronous receiver transmitter (UART) or serial peripheral interface (SPI) interface and may be coupled to the micro-controller 716. The micro-controller 716 may translate vehicle input based on, or including, data from the sensor module 710. The translated vehicle input may include a video signal that is transferrable to an image buffer in the active headlamp 718. In addition, the micro-controller 716 may load default image frames and test for open/short pixels during startup. In embodiments, an SPI interface may load an image buffer in CMOS. Image frames may be full frame, differential or partial frames. Other features of micro-controller 716 may include control interface monitoring of CMOS status, including die temperature, as well as logic LDO output. In embodiments, LED DC/DC output may be dynamically controlled to minimize headroom. In addition to providing image frame data, other headlamp functions, such as complementary use in conjunction with side marker or turn signal lights, and/or activation of daytime running lights, may also be controlled.

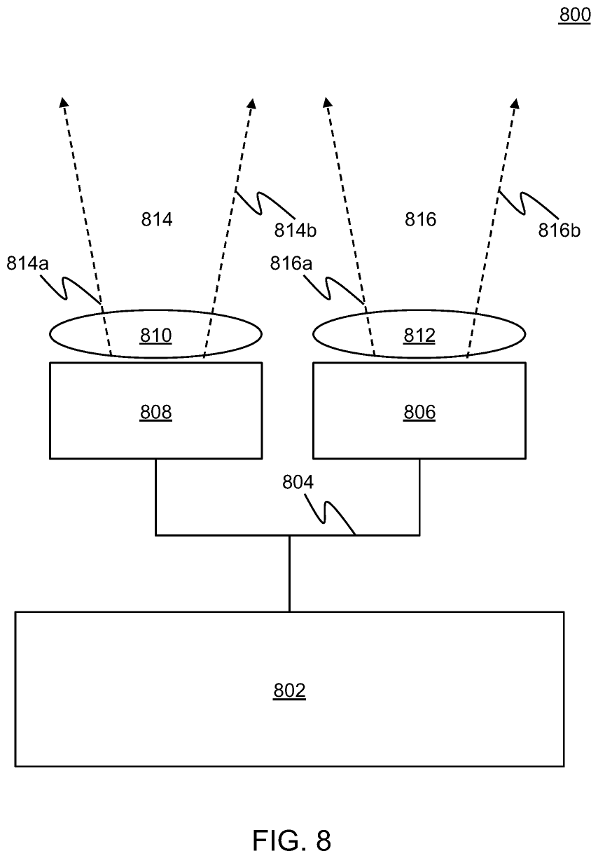

FIG. 8 is a diagram of another example vehicle headlamp system 800. The example vehicle headlamp system 800 illustrated in FIG. 8 includes an application platform 802, two LED lighting systems 806 and 808, and secondary optics 810 and 812. The lighting systems 100, 200 and 300 may be incorporated into the LED lighting systems 806 and/or 808.

The LED lighting system 808 may emit light beams 814 (shown between arrows 814a and 814b in FIG. 8). The LED lighting system 806 may emit light beams 816 (shown between arrows 816a and 816b in FIG. 8). In the embodiment shown in FIG. 8, a secondary optic 810 is adjacent the LED lighting system 808, and the light emitted from the LED lighting system 808 passes through the secondary optic 810. Similarly, a secondary optic 812 is adjacent the LED lighting system 806, and the light emitted from the LED lighting system 806 passes through the secondary optic 812. In alternative embodiments, no secondary optics 810/812 are provided in the vehicle headlamp system. The light beams 816 have the wavelengths of the light that is emitted by the lighting systems 100, 200 and 300 respectively.

Where included, the secondary optics 810/812 may be or include one or more light guides. The one or more light guides may be edge it or may have an interior opening that defines an interior edge of the light guide. LED lighting systems 808 and 806 may be inserted in the interior openings of the one or more light guides such that they inject light into the interior edge (interior opening light guide) or exterior edge (edge lit light guide) of the one or more light guides. In embodiments, the one or more light guides may shape the light emitted by the LED lighting systems 808 and 806 in a desired manner, such as, for example, with a gradient, a chamfered distribution, a narrow distribution, a wide distribution, or an angular distribution.

The application platform 802 may provide power and/or data to the LED lighting systems 806 and/or 808 via lines 804, which may include one or more or a portion of the power lines 702 and the data bus 704 of FIG. 7. One or more sensors (which may be the sensors in the vehicle headlamp system 800 or other additional sensors) may be internal or external to the housing of the application platform 802. Alternatively, or in addition, as shown in the example vehicle headlamp system 700 of FIG. 7, each LED lighting system 808 and 806 may include its own sensor module, connectivity and control module, power module, and/or LED array.

In embodiments, the vehicle headlamp system 800 may represent an automobile with steerable light beams where LEDs may be selectively activated to provide steerable light. For example, an array of LEDs or emitters may be used to define or project a shape or pattern or illuminate only selected sections of a roadway. In an example embodiment, infrared cameras or detector pixels within LED lighting systems 806 and 808 may be sensors (e.g., similar to sensors in the sensor module 710 of FIG. 7) that identify portions of a scene (e.g., roadway or pedestrian crossing) that require illumination.

As would be apparent to one skilled in the relevant art, based on the description herein, embodiments of the present invention can be designed in software using a hardware description language (HDL) such as, for example, Verilog or VHDL. The HDL-design can model the behavior of an electronic system, where the design can be synthesized and ultimately fabricated into a hardware device. In addition, the HDL-design can be stored in a computer product and loaded into a computer system prior to hardware manufacture.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

1. A lighting device comprising:
a light source that comprises a light-emitting top surface that emits a first light and a bottom surface opposite the light-emitting top surface;
a first wavelength converting layer that comprises a top surface and a bottom surface, opposite the top surface, which completely covers the top surface of the light source such that the first wavelength converting layer receives the first light via the bottom surface, absorbs a first portion of the first light, passes a second portion of the first light via the top surface and emits a second light in the infrared (IR) spectral range via the top surface in response to absorbing the first portion of the first light; and
a second wavelength converting layer that comprises a top surface and a bottom surface, opposite the top surface, wherein the bottom surface of the second wavelength converting layer is over the top surface of the first wavelength converting layer, and wherein the second wavelength converting layer absorbs the second portion of the first light, passes the second light via the top osurface and emits a third light at least in the visible spectral range via the top surface in response to absorbing the second portion of the first light.

2. The lighting device according to claim 1, wherein the second light has a peak wavelength between 700-1050 nm.

3. The lighting device according to claim 1, wherein the third light has a peak wavelength between 470-1050 nm.

4. The lighting device according to claim 1, wherein the third light has a peak wavelength between 600-700 nm.

5. The lighting device according to claim 1, wherein the first light has a peak wavelength between 430-470 nm.

6. The lighting device according to claim 1, wherein the first wavelength converting layer and the second wavelength converting layer are stacked on the light source.

7. The lighting device according to claim 1, wherein the first wavelength converting layer contains Cr(III) doped garnet phosphors according to:
$${Gd}_{3 - x} {RE}_{x} {Sc}_{2 - y - z} {Ln}_{y} {Ga}_{3 - w} {Al}_{w} {O}_{12} : {Cr}_{z} ( Ln = Lu , Y , Yb , Tm ; RE = La , Nd ) ,$$
$$where 0 \leq x \leq 3 ; 0 \leq y \leq 1.5 ; 0 \leq z \leq 0.3 ; and 0 \leq w \leq 2 such as$$
$${Gd}_{2.8} {La}_{0.2} {Sc}_{1.7} {Lu}_{0.2} {Ga}_{3} {O}_{12} : {Cr}_{01} or$$
$${Gd}_{2.66} {Yb}_{0.2} {Sc}_{1.75} {Lu}_{0.3} {Ga}_{2} {AlO}_{12} : {Cr}_{0.1} .$$

8. The lighting device according to claim 1, wherein the first wavelength converting layer contains Cr(III) doped pyroxene phosphors according to:
$${E}_{1 - w} {Sc}_{1 - x - y - u - w} {M}_{y} {Z}_{u} {A}_{2 w} {Si}_{2 - z - u} {Ge}_{z} {Al}_{u} {O}_{6} : {Cr}_{x} , such as$$
$${Li}_{1 - w} {Sc}_{1 - x - w} {Mg}_{2 w} {Si}_{2} {O}_{6} : {Cr}_{x} ( 0.1 \leq w \leq 0.4 ) .$$

9. The lighting device according to claim 1, wherein the first wavelength converting layer contains Cr(III) doped borate phosphors according to:
$${Sc}_{1 - x - y} {A}_{y} {BO}_{3} : {Cr}_{x} ( A = Lu , In , Yb , Tm , Y , Ga , Al ; 0 < x \leq 0.5 , 0 < y \leq 0.9 ) .$$

10. A lighting device comprising:
a light source that emits a first light;
a first wavelength converting layer that receives the first light, absorbs a first portion of the first light, passes a second portion of the first light and emits a second light in response to absorbing the first portion of the first light;
a second wavelength converting layer that absorbs the second portion of the first light, passes the second light and emits a third light in response to absorbing the second portion of the first light; and
a reflective layer that passes the second light and reflects the third light through the second wavelength converting layer to the first wavelength converting layer, wherein the first wavelength converting layer emits additional amounts of the second light in response to absorbing the second light.

11. The lighting device according to claim 10, wherein the second light has a peak wavelength between 700-1050 nm.

12. The lighting device according to claim 10, wherein the second light has a peak wavelength between 1100-1700 nm.

13. The lighting device according to claim 10, wherein the first light has a peak wavelength between 430-470 nm.

14. The lighting device according to claim 10, wherein the first wavelength converting layer and the second wavelength converting layer are stacked on the light source.

15. The lighting device according to claim 10, wherein the first wavelength converting layer contains Cr(III) doped garnet phosphors according to:
$${Gd}_{3 - x} {RE}_{x} {Sc}_{2 - y - z} {Ln}_{y} {Ga}_{3 - w} {Al}_{w} {O}_{12} : {Cr}_{z} ( Ln = Lu , Y , Yb , Tm ; RE = La , Nd ) ,$$
$$where 0 \leq x \leq 3 ; 0 \leq y \leq 1.5 ; 0 \leq z \leq 0.3 ; and 0 \leq w \leq 2 such as$$
$${Gd}_{2.8} {La}_{0.2} {Sc}_{1.7} {Lu}_{0.2} {Ga}_{3} {O}_{12} : {Cr}_{01} or$$
$${Gd}_{2.66} {Yb}_{0.2} {Sc}_{1.75} {Lu}_{0.3} {Ga}_{2} {AlO}_{12} : {Cr}_{0.1} .$$

16. The lighting device according to claim 10, wherein the first wavelength converting layer contains Cr(III) doped pyroxene phosphors according to:
$${E}_{1 - w} {Sc}_{1 - x - y - u - w} {M}_{y} {Z}_{u} {A}_{2 w} {Si}_{2 - z - u} {Ge}_{z} {Al}_{u} {O}_{6} : {Cr}_{x} , such as$$
$${Li}_{1 - w} {Sc}_{1 - x - w} {Mg}_{2 w} {Si}_{2} {O}_{6} : {Cr}_{x} ( 0.1 \leq w \leq 0.4 ) .$$

17. The lighting device according to claim 10, wherein the first wavelength converting layer contains Cr(III) doped borate phosphors according to:
$${Sc}_{1 - x - y} {A}_{y} {BO}_{3} : {Cr}_{x} ( A = Lu , In , Yb , Tm , Y , Ga , Al ; 0 < x \leq 0.5 , 0 < y \leq 0.9 ) .$$

18. A method of manufacturing a lighting device comprising:
forming a light source that comprises a light-emitting top surface, that emits a first light, and a bottom surface opposite the light-emitting top surface;
forming a first wavelength converting layer over the light-emitting top surface of the light source such that the first wavelength converting layer completely covers the top surface of the light source and that-receives the first light via the bottom surface, absorbs a first portion of the first light, passes a second portion of the first light via the top surface and emits a second light via the top surface in response to absorbing the first portion of the first light; and
forming a second wavelength converting layer over the top surface of the first wavelength converting layer that absorbs the second portion of the first light, passes the second light and emits a third light in response to absorbing the second portion of the first light.

19. The method according to claim 18, wherein the second light has a peak wavelength between 700-1050 nm.

20. The method according to claim 18, wherein the third light has a peak wavelength between 470-1050 nm.

21. The method according to claim 18, wherein the third light has a peak wavelength between 600-700 nm.
